(19) United States
(12) Patent Application Publication
(10) Pub. No.: US 2009/0298699 A1
(43) Pub. Date: Dec. 3, 2009

(54) PROCESS FOR PRODUCING RAW MATERIAL POWDER FOR OXIDE SUPERCONDUCTOR

(75) Inventor: Naoki Ayai, Osaka (JP)

Correspondence Address: DRINKER BIDDLE & REATH (DC), 1500 K STREET, N.W., SUITE 1100, WASHINGTON, DC, 20005-1209, US

(73) Assignee: SUMITOMO ELECTRIC INDUSTRIES ,LTD., Osaka-shi ,Osaka (JP)

(21) Appl. No.: 12/441,203

(22) PCT Filed: Mar. 13, 2008
(86) PCT No.: PCT/JP2008/054572

§ 371 Date: Mar. 13, 2009

(30) Foreign Application Priority Data
Jul. 18, 2007 (JP) 2007-187075

(51) Int. Cl. H01L 39/24; C01G 29/00; C01G 21/06; C01F 11/18; C01G 3/02

(52) U.S. Cl. 505/425; 423/617; 423/619; 423/430; 423/604

(57) ABSTRACT

The invention offers a production method of a material powder of an oxide superconductor. The production method is provided with both a step of producing a dry powder by removing solvent from a solution containing elements for constituting the oxide superconductor and a step of producing oxides of the elements for constituting the oxide superconductor by scattering the dry powder in a high-temperature furnace. Provided with the above steps, the production method not only can achieve the uniform presence of the elements for constituting the oxide superconductor but also enables the mass production of the material powder.

### TECHNICAL FIELD

The present invention relates to a production method of a material powder of an oxide superconductor, particularly to a production method of the material powder in which elements for constituting the oxide superconductor are uniformly dispersed.

### BACKGROUND ART

A spray-drying method (or a freeze-drying method) and a spray pyrolysis method have been proposed as a production method of a material powder of an oxide superconductor (see, for example, Patent literatures 1 and 2).

A spray-drying method (or a freeze-drying method) is performed through the following procedure. First, a nitrate solution containing the elements for constituting an oxide superconductor is dried with a spray-dryer (or by freeze drying) to produce a nitrate powder. At this stage, water in the solution merely evaporates without causing a chemical reaction. Next, the nitrate powder is heat-treated in a heat-treating furnace (such as a batch-type furnace or a belt-conveying-type continuous furnace) to synthesize an oxide powder. Subsequently, the oxide powder is pulverized to be mixed. The above-described spray-drying method (or the freeze-drying method) can perform the drying by using hot air at 100° C. or so. Consequently, it can perform a mass treatment, so that it can produce a large amount of material powder of an oxide superconductor.

A spray pyrolysis method is a method of synthesizing a material powder of an oxide superconductor in one process by spraying a nitrate solution containing the elements for constituting of an oxide superconductor into a high-temperature reaction furnace having a temperature not lower than the decomposition temperatures of all of the contained nitrates. The spray pyrolysis method instantaneously synthesizes the material powder of an oxide superconductor out of a nitrate solution. Therefore, it can produce a material powder of an oxide superconductor that is fine and homogeneous and that is free from segregation and aggregation.

Patent literature 1: the published Japanese patent application Tokukai 2006-45055

Patent literature 2: the published Japanese patent application Tokukai 2006-240980.

### DISCLOSURE OF THE INVENTION

### Problem to be Solved by the Invention

For the conventional spray-drying method and freeze-drying method, in the process of synthesizing an oxide powder by heat-treating a nitrate powder, because the decomposition temperatures of the nitrates differ from one another depending on the contained elements, segregation and aggregation of the elements occur. After the heat treatment is completed, the oxide powder is pulverized and mixed. Nevertheless, the homogeneity is poor even after the mixing. As a result, the conventional method has a problem in that there exists a limitation in the improvement in the superconducting property of the oxide superconductor.

In addition, the conventional spray pyrolysis method has a problem in that the method cannot mass-produce the material powder of an oxide superconductor. More specifically, the method needs to perform both the evaporation of water and the pyrolysis of the nitrates instantaneously in a reaction furnace. However, when the sprayed amount of the nitrate solution is large, the temperature in the furnace is decreased. Therefore, the sprayed amount must be limited. In addition, because a large amount of water vapor is produced in the reaction furnace, a turbulent flow is generated in the reaction furnace. The turbulent flow causes the adhesion and deposition of the synthesized oxide powder onto the furnace wall. As a result, the furnace cannot be stably operated for a long time. As described above, it becomes difficult to increase the amount of production of the material powder of an oxide superconductor. This difficulty has increased the production cost of the material powder of an oxide superconductor.

In view of the above-described circumstances, a main object of the present invention is to offer a production method of a material powder of an oxide superconductor, the method enabling both the uniform presence of the elements for constituting the oxide superconductor in the powder and the mass production of the powder.

### Means to Solve the Problem

The method of the present invention for producing a material powder of an oxide superconductor is provided with a step of producing a dry powder by removing solvent from a solution containing elements for constituting the oxide superconductor. The method is also provided with a step of producing oxides of the above-described elements by scattering the dry powder in a high-temperature furnace.

In this case, in the solution containing the elements for constituting the oxide superconductor, the individual elements are micromixed at the atomic level. Consequently, the dry powder produced by removing the solvent from the solution is in a state where the individual elements are micromixed at the atomic level. By scattering the foregoing dry powder in the high-temperature furnace, oxides of the individual elements for constituting the oxide superconductor are instantaneously synthesized. Consequently, a fine, homogeneous material powder of the oxide superconductor can be produced in which the metal-element components for constituting the oxide superconductor are dispersed without being segregated or aggregated. Furthermore, it is not necessary to pulverize and mix the heat-treated oxide powder.

The above-described solvent may be a nitric acid solution. By using nitric acid, the individual elements for constituting the oxide superconductor can be dissolved in the solution completely without forming the passive state. In the case of the above-described method of synthesizing oxides, when the temperature in the high-temperature furnace is maintained at a temperature not lower than the decomposition temperatures of all of the nitrates extracted from the solution, oxides of the elements for constituting the oxide superconductor can be synthesized in the high-temperature furnace. The oxide powder is produced by scattering in the high-temperature furnace a dry powder that is produced by removing water in the previous step. Therefore, heat is not taken from the inside of the high-temperature furnace due to the evaporation of water. Consequently, even when the amount of treatment is increased to the extent corresponding to the amount of that heat, the high temperature in the furnace can be maintained. Furthermore, because a large amount of water vapor is not produced in the high-temperature furnace, the oxide powder is unlikely to adhere or be deposited onto the furnace wall. Therefore, the furnace can be operated for a long time under a stable condition. This feature enables the mass production of the material powder of the oxide superconductor. In the above description, the term “a high-temperature furnace” means a heating furnace that can achieve a heating temperature not lower than the decomposition temperatures of all of the nitrates contained in the solution. As described above, it is desirable that the inside temperature of the high-temperature furnace be set at a temperature not lower than the decomposition temperatures of all of the nitrates.

It is desirable that in the step of producing oxides, the dry powder be mixed with a carrier gas before the dry powder is scattered in the high-temperature furnace. When this condition is satisfied, because a gas mixed with the dry powder is injected into the high-temperature furnace, the dry powder is injected into the high-temperature furnace with the shape of a spray. Therefore, the dry powder can be scattered readily in the high-temperature furnace. The carrier gas may be a dried atmospheric gas.

In addition, it is desirable that in the step of producing a dry powder, the solvent be removed from the solution by either a spray-drying method or a freeze-drying method. When this condition is satisfied, a large amount of dry powder can be produced at low cost by a spray-drying method or a freeze-drying method. A method that mechanically mixes solid salts of the elements for constituting the oxide superconductor has difficulty in mixing the individual elements at the atomic level. On the other hand, according to the present invention, the individual elements are first micromixed at the atomic level in a solution. Subsequently, a dry powder is produced by removing the solvent from the solution. Thus, a dry powder in which the individual elements are mixed at the atomic level can be obtained. In other words, a fine, homogeneous material powder of the oxide superconductor can be produced.

### Effect of the Invention

The method of the present invention for producing a material powder of an oxide superconductor enables the uniform presence of the elements for constituting the oxide superconductor in the material powder of the oxide superconductor. The method also enables the mass production of the material powder of the oxide superconductor.

### BRIEF DESCRIPTION OF THE DRAWING

FIG. 1 is a flow chart showing a method of the present invention for producing a material powder of an oxide superconductor.

FIG. 2 is a schematic diagram showing the structure of a drying furnace.

FIG. 3 is a schematic diagram showing the structure of a high-temperature furnace and other components of an apparatus for producing a material powder of an oxide superconductor.

### EXPLANATION OF THE SIGN

1: Material powder of an oxide superconductor
2: Dry powder
10: Spray dryer
11: Drying chamber
12: Nozzle
13: Container
14 and 15: Arrow
16: Duct
17: Spray
20: Powder fixed-amount feeder
21: Feeding outlet
22: Hopper
23: Transfer tube
24: Arrow
30: High-temperature furnace
31: Heat source
32: Nozzle
34: Hopper portion
35: Transfer tube
36: Arrow
40: Powder collector
41: Filter
42: Powder-collecting container
44: Discharging tube
45: Arrow

### BEST MODE FOR CARRYING OUT THE INVENTION

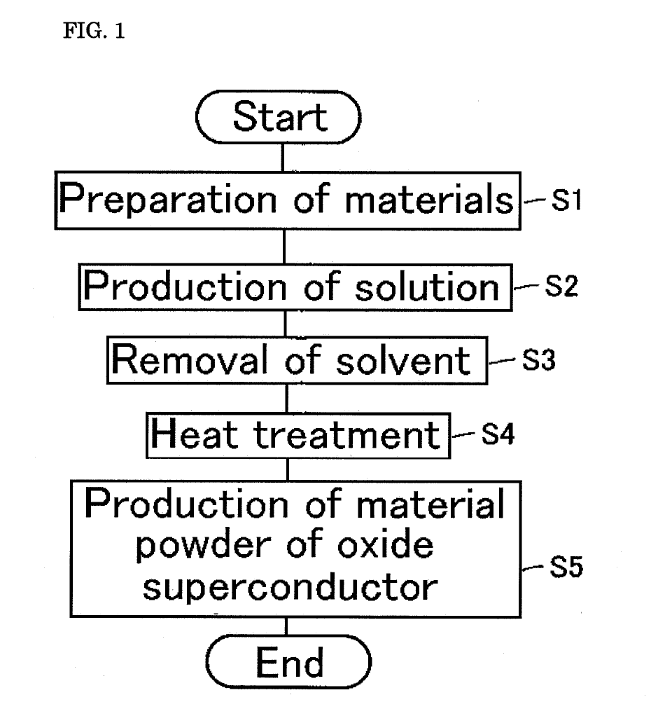

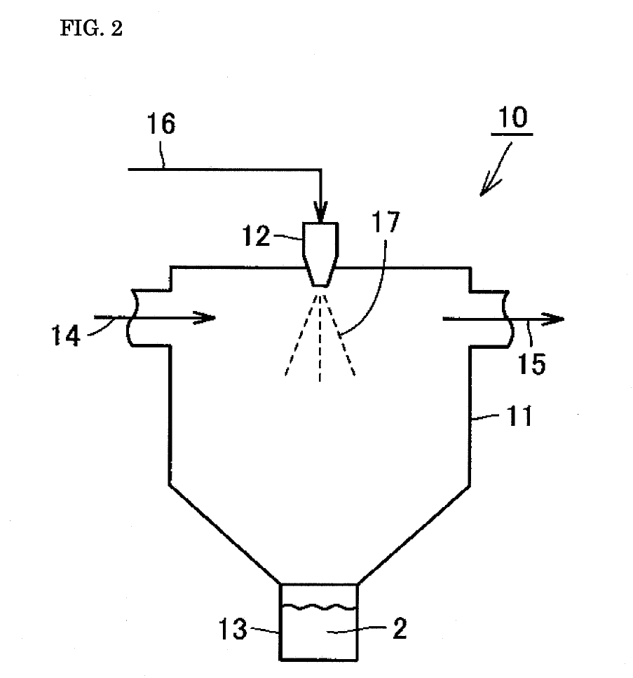

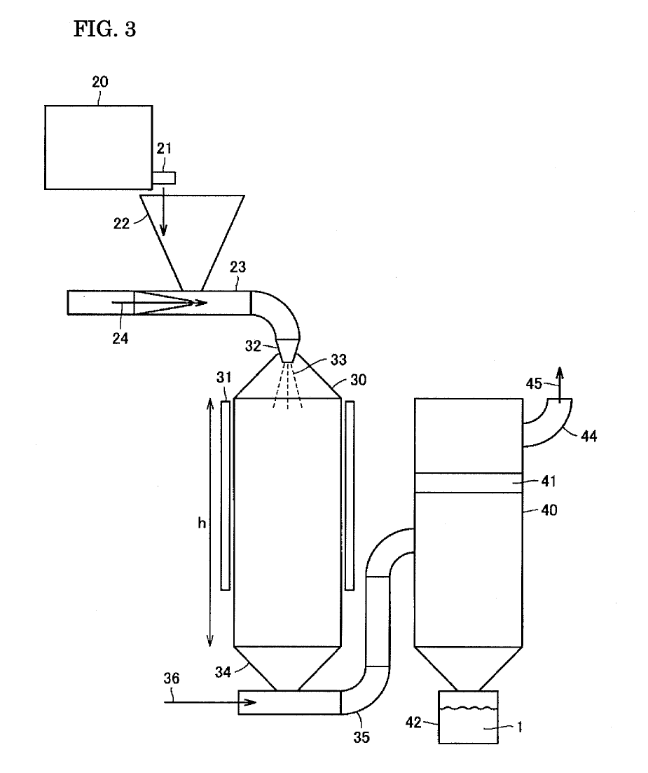

Embodiments of the present invention are explained below based on the drawing. In the drawing, the ratios of the dimensions are not necessarily coincident with those of the explanation. FIG. 1 is a flow chart showing a method of the present invention for producing a material powder of an oxide superconductor. FIG. 2 is a schematic diagram showing the structure of a drying furnace for producing a dry powder. FIG. 3 is a schematic diagram showing the structure of a high-temperature furnace and other components of an apparatus for producing a material powder of an oxide superconductor. The production method of a material powder of an oxide superconductor is explained below by referring to FIGS. 1 to 3.

As shown in FIG. 1, first, Step S1 prepares materials containing the elements for constituting the material powder of an oxide superconductor. The types of oxide superconductor include a bismuth-based oxide exhibiting a superconducting phenomenon at a temperature of 110 K and an yttrium-based oxide exhibiting a superconducting phenomenon at a temperature of 90 K. In the case of a bismuth-based superconductor, such as Bi2223 and Bi2212, materials containing bismuth, lead, strontium, calcium, and copper are prepared. For example, powders of materials of Bi₂O₃, PbO, SrCO₃, CaCO₃, and CuO may be prepared. Solid metals, such as, Bi, Pb, Sr, Ca, and Cu, may also be used. In addition, Bi(NO₃)₃, Pb(NO₃)₂, Sr(NO₃)₂, Ca(NO₃)₂, Cu(NO₃)₂ or hydrates of these compounds, for example, may also be prepared. A carbon component contained in these materials can be removed from the materials as carbon dioxide at the time of dissolving. Nevertheless, it is more desirable that the materials contain the least possible amount of carbon component.

Next, Step S2 produces a solution of the materials prepared in Step S1. As the solvent, it is desirable to use nitric acid. Because it can dissolve the individual materials completely without forming the passive state of the materials, the content of the carbon component can be decreased to zero in theory. Nevertheless, the solvent is not limited to nitric acid. Other inorganic acid, such as sulfuric acid or hydrochloric acid, may also be used. Organic acid, such as oxalic acid or acetic acid, may also be used. Furthermore, not only an acid but also an alkaline solution may be used on condition that the solvent can dissolve the materials.

For example, the materials prepared in Step S1 are tailored so that the ratio (Bi, Pb):Sr:Ca:Cu can have an element ratio of 2:2:2:3. Then, the tailored materials are dissolved in a nitric acid solution to be ionized in the solution. At this moment, the temperature of the solution is not particularly limited. It is essential only that the temperature enable the sufficient dissolution of bismuth and the like. In addition, to achieve a sufficient degree of dissolution, the solution may be stirred with an agitation blade.

As described above, by completely dissolving the individual materials in the solution, the individual elements for constituting the material powder of the oxide superconductor (the elements: bismuth, lead, strontium, calcium, and copper) are micromixed at the atomic level in the solution.

Next, Step S3 removes the solvent from the solution of the materials containing the elements for constituting the material powder of the oxide superconductor. For example, by using a spray dryer 10 shown in FIG. 2, the solvent can be removed to produce a dry powder 2. As shown in FIG. 2, the spray dryer 10 is provided with a drying chamber 11, a nozzle 12 for atomizing the solution into the drying chamber 11, and a container 13 for gathering and storing the dry powder 2 produced by removing the solvent from the solution (i.e., by drying).

A solution, such as a nitrate solution of bismuth, lead, strontium, calcium, and copper all for constituting the material powder of the oxide superconductor, enters the nozzle 12 after passing through a duct 16. The nozzle 12 may be a two-fluid nozzle, for example. The solution is injected into the drying chamber 11 together with an atomizing gas to form a spray 17. The atomizing gas may be pressurized dry air. A nitrogen gas may also be used. When a two-fluid nozzle is used, the solution can be injected into the drying chamber 11 as fine droplets each having a diameter of 100 μm or less. However, there is a drawback in that the amount of treatment is rather small for using the two-fluid nozzle. Nevertheless, an ultrasonic atomizer may also be used. In this case, much finer droplets can be obtained.

The nozzle 12 injects into the spray dryer 10 the nitrate solution in which the individual elements for constituting the material powder of the oxide superconductor are micromixed at the atomic level. Therefore, it is necessary to perform the drying while maintaining the state where the individual elements are uniformly dispersed without being segregated. To meet this requirement, while the drying treatment is performed, the temperature of the drying chamber 11 is controlled so that the temperature of the dry powder 2 can be maintained in the range of higher than 90° C. and lower than 110° C., which is the temperature range for producing the intended complex-nitrate crystals. The reason is that if the temperature of the dry powder 2 becomes 90° C. or lower or 110° C. or higher, some of the nitrates of the individual elements are decomposed or melted, thereby increasing the possibility of the occurring of aggregation and segregation.

For example, the temperature in the drying chamber 11 can be maintained by the following process. First, as shown by an arrow 14, hot air is fed into the drying chamber 11. Then, the solution injected into the drying chamber 11 (i.e., the spray 17) takes the thermal energy from the hot air in order to evaporate the solvent. The hot air having given the thermal energy is discharged as shown by an arrow 15.

When the solution is a nitrate solution, the dry powder 2 is composed of nitrate powders of bismuth, lead, strontium, calcium, and copper all for constituting the material powder of the oxide superconductor. At the time the elements for constituting the material powder of the oxide superconductor are dissolved in the solution, they are micromixed at the atomic level. Because the solvent is removed from the solution by using the spray drying, the individual elements maintain the state where they are uniformly dispersed in the dry powder 2 without being aggregated or segregated. In other words, a nitrate powder can be produced in which the individual elements are micromixed at the atomic level. The conventional method mechanically mixes solid nitrates of the individual elements. This method has been unable to perform the mixing of the individual elements at the atomic level.

The method of removing the solvent from the solution is not limited to the spray dryer 10 shown in FIG. 2. For example, a freeze-drying apparatus may be used to freeze-dry the solution to produce the dry powder 2. Another method than the spray drying and freeze drying may also be used provided that the method can remove the solvent from the solution to produce the dry powder 2.

Next, Step S4 heat-treats the dry powder 2. More specifically, the dry powder is scattered in a high-temperature furnace to oxidize bismuth, lead, strontium, calcium, and copper all for constituting the oxide superconductor so that oxide powders can be produced. To perform this process, an apparatus shown in FIG. 3 may be used, for example. In FIG. 3, the nitrate powder produced in the previous step S3 is filled in a fixed-amount powder feeder 20. The fixed-amount powder feeder 20 is provided with a feeding outlet 21. A fixed amount of nitrate powder falls from the feeding outlet 21 to a hopper 22 at fixed intervals.

The hopper 22 is connected to a transfer tube 23 at an outlet at the bottom. The transfer tube 23 is fed with compressed air as a carrier gas as shown by an arrow 24. The nitrate powder having fallen from the outlet of the hopper 22 to the inside of the transfer tube 23 is mixed with compressed air and travels along the inside of the transfer tube 23. It arrives at a nozzle 32 attached to a high-temperature furnace 30.

The high-temperature furnace 30 may be, for example, an electric furnace provided with a heat source 31 at its circumference. The high-temperature furnace 30 may have a height of “h” to secure a passing time of the nitrate powder needed to completely pyrolyze the nitrates (for example, the passing time is at least one second and at most 30 seconds). For example, the height “h” may be two meters. In addition, at least one part of the inside of the high-temperature furnace 30 (for example, a length of 300 mm in the direction of the height of the furnace) may be maintained at a temperature not lower than the decomposition temperatures of all of the nitrates contained in the nitrate powder. For example, the temperature to be maintained is at least 600° C. and at most 850° C.

The nozzle 32 is attached to the top portion of the high-temperature furnace 30. The nitrate powder having travelled to the nozzle 32 with the help of the compressed air passes through the nozzle 32, mixes with the compressed air, and scatters in the high-temperature furnace 30. At this moment, it is desirable that the compressed air be dry (for example, the air contain water at a concentration of at most 1 vol. %) because this condition decreases the adverse effect of decreasing the temperature in the high-temperature furnace 30. Because the inside of the high-temperature furnace 30 is maintained at a temperature not lower than the decomposition temperatures of the nitrates, the nitrate powder having scattered in the high-temperature furnace 30 instantaneously causes both the pyrolytic reaction of the nitrates and the reaction between the pyrolyzed metal oxides. The reaction produces an oxide powder in which fine oxides of the individual metal-element components for constituting the oxide superconductor are dispersed uniformly without being segregated or aggregated.

The nitrate powder scattering in the high-temperature furnace 30 is in a dry state where water in it has been already removed. Therefore, no heat is taken from the inside of the high-temperature furnace 30 due to the evaporation of water. Furthermore, because a large amount of water vapor is not produced in the high-temperature furnace 30, the oxide powder produced by the oxidation of the nitrate powder is unlikely to adhere or be deposited onto the furnace wall.

The high-temperature furnace 30 is provided with a hopper portion 34 at its bottom portion. The hopper portion 34 has an outlet at its bottom portion. The outlet is connected to a transfer tube 35. The transfer tube 35 is fed with dry air for dilution and cooling as shown by an arrow 36. The oxide powder having fallen from the outlet of the hopper portion 34 to the inside of the transfer tube 35 travels along the inside of the transfer tube 35 while being cooled by the dry air for dilution and cooling, with the dry air taking the heat from the powder. The oxide powder arrives at the inside of a powder collector 40.

The dry air for dilution and cooling flows from the powder collector 40 to a discharging tube 44 and is discharged to the outside of the system as shown by an arrow 45. The oxide powder moves in the powder collector 40 together with the dry air for dilution and cooling. The oxide powder is then captured by a filter 41 provided at the inside of the powder collector 40. The oxide powder falls in the powder collector 40 to be collected by and stored in a powder-collecting container 42 provided at the bottom portion of the powder collector 40.

As described above and as shown as Step S5, the oxide powder stored in the powder-collecting container 42 of the powder collector 40 is taken out to be used as a material powder 1 of an oxide superconductor, which is a precursor of the oxide superconductor. The material powder 1 is used to produce an oxide superconductor such as an oxide superconducting wire. The term “precursor” is used to mean one of a series of substances in an intermediate state between the starting material and the intended product. Usually, however, the term indicates the substance in the immediately preceding stage.

As explained above, to produce the material powder 1 of an oxide superconductor, which is a precursor of the oxide superconductor, the individual elements are first micromixed at the atomic level in the solution. The solvent is removed from the solution to form a dry powder in which the individual elements are mixed at the atomic level. By scattering in the high-temperature furnace 30 the dry powder 2 in which the individual elements are mixed at the atomic level, oxides of the individual elements for constituting the oxide superconductor are instantaneously synthesized. Consequently, a fine, homogeneous material powder 1 of the oxide superconductor can be produced in which the metal-element components for constituting the oxide superconductor are dispersed without being segregated or aggregated.

Because the oxide powder is produced by scattering the dry powder 2 in the high-temperature furnace 30, heat is not taken from the inside of the high-temperature furnace 30 due to the evaporation of water. Consequently, even when the amount of treatment is increased to the extent corresponding to the amount of that heat, the high temperature in the furnace can be maintained. Furthermore, because a large amount of water vapor is not produced in the high-temperature furnace 30, the oxide powder is unlikely to adhere or be deposited onto the furnace wall. Therefore, the furnace can be operated for a long time under a stable condition. This feature enables the mass production of the material powder 1 of the oxide superconductor.

The material powder of the oxide superconductor produced according to the above description is filled in a sheath made of metal, such as silver or silver alloy, which has high thermal conductivity. The sheath filled with the powder is mechanically processed and heat-treated to produce an oxide superconducting wire. An oxide superconducting wire can be used for a superconducting apparatus, such as a superconducting cable, superconducting transformer, superconducting fault-current limiter, and superconducting magnetic energy storage.

### EXAMPLE

An example of the present invention is explained below. A sample was produced in accordance with the method of the present invention for producing a material powder of an oxide superconductor to carry out an experiment to clarify its superconducting property. Samples were also produced as Comparative examples through the conventional spray-drying method and spray pyrolysis method. Concrete methods of producing the samples used for the experiment are explained below.

### Spray-Drying Method

A nitrate solution was prepared that had a Bi—Pb—Sr—Ca—Cu ratio of 1.78:0.35:2.0:2.0:3.0 and a density of 1.4 g/cc. The solution was dried at a temperature between 90° C. and 110° C. using the spray-drying apparatus shown in FIG. 2 to obtain a nitrate powder. The nitrate powder was heat-treated for eight hours at 780° C. in an electric furnace. The powder was subjected to pulverizing and mixing treatments so that the constituents aggregated by the heat treatment could be dispersed under a finely pulverized condition. The nitrate powder was further heat-treated for eight hours at 780° C. to produce a material powder of the oxide superconductor.

### Spray Pyrolysis Method

A nitrate solution was prepared that had a Bi—Pb—Sr—Ca—Cu ratio of 1.78:0.35:2.0:2.0:3.0 and a density of 1.4 g/cc. The solution was directly sprayed into an atmosphere at a maximum temperature of 820° C. using a spray pyrolysis apparatus. This operation dries and denitrates the solution to synthesize an oxide powder. The oxide powder was heat-treated for eight hours at 780° C. in an electric furnace to produce a material powder of the oxide superconductor.

### The Method of the Present Invention

A nitrate solution was prepared that had a Bi—Pb—Sr—Ca—Cu ratio of 1.78:0.35:2.0:2.0:3.0 and a density of 1.4 g/cc. The solution was dried at a temperature between 90° C. and 110° C. through the spray-drying method to obtain a nitrate powder. The nitrate powder was mixed with compressed air and scattered in an atmosphere at a maximum temperature of 800° C. using the dry-powder-heating apparatus shown in FIG. 3. This operation decomposed the nitrates to produce an oxide powder. The oxide powder was heat-treated for four hours at 780° C. to remove the water and nitric acid both adhering to the oxide powder. Thus, a material powder of the oxide superconductor was produced.

The material powders of the oxide superconductor produced through the above-described three types of methods were used to produce 85-filament tape-shaped silver-sheathed wires each having a width of 4 mm, a thickness of 0.22 mm, and a silver ratio of 1.7 through the powder-in-tube method.

The individual samples were subjected to measurement of a critical-current value, Ic, in a self-magnetic field in liquid nitrogen at a temperature of 77 K. The critical current was measured with a four-terminal method and is defined as a current that generates an electric field of 1 μV/cm. The measured results of the critical-current density are as follows:

Sample produced through the spray-drying method: 39 kA/cm²

Sample produced through the spray pyrolysis method: 57 kA/cm²

Sample produced through the production method of the present invention: 58 kA/cm².

In addition, the individual samples underwent the examination of the amount of production per hour of the material powder of the oxide superconductor. The examined results are as follows: The spray-drying method, the spray pyrolysis method, and the method of the present invention each have a material-producing capability that is proportional to the heating capacity (heater capacity) of the apparatus of the individual method. When the heating capacity (heater capacity) is set at 50 kW, the amounts of production per hour are as follows:

Sample produced through the spray-drying method: 2 kg/hr

Sample produced through the spray pyrolysis method: 0.3 kg/hr

Sample produced through the production method of the present invention: 2 kg/hr.

The above-described results can be summarized as follows. The sample produced through the production method of the present invention has an amount of production per unit time of the material powder of the oxide superconductor comparable to that of the sample produced through the spray-drying method, which is a comparative example. However, it has a critical-current value about 1.5 times that of the comparative example, which is a significant increase. In addition, the sample of the present invention has a critical-current value comparable to that of the sample produced through the spray pyrolysis method. However, it has an amount of production per unit time of the material powder of the oxide superconductor more than 6 times that of the spray pyrolysis method, which is a significant increase. The above results show the following features. The oxide superconductor obtained by the production method of the present invention has a superior superconducting property. In addition, the production method of the present invention can mass-produce a material powder of an oxide superconductor.

It is to be considered that the above-disclosed embodiments and example are illustrative and not restrictive in all respects. The scope of the present invention is shown by the scope of the appended claims, not by the above-described explanations. Accordingly, the present invention is intended to cover all revisions and modifications included within the meaning and scope equivalent to the scope of the claims.

### INDUSTRIAL APPLICABILITY

The method of the present invention for producing a material powder of an oxide superconductor not only can achieve the uniform presence of the elements for constituting the oxide superconductor but also enables the mass production of the material powder.

1. A method of producing a material powder of an oxide superconductor, the method comprising the steps of:
(a) producing a dry powder by removing solvent from a complex-metallic-salt solution containing elements for constituting the oxide superconductor, the removing operation being performed at a temperature lower than decomposition temperatures of the individual metallic salts; and
(b) producing oxides of the elements by scattering the dry powder in a high-temperature furnace having a temperature not lower than the decomposition temperatures of the individual metallic salts.

2. The method of producing a material powder of an oxide superconductor as defined by claim 1, wherein in the step of producing oxides, the dry powder is mixed with a carrier gas before the dry powder is scattered in the high-temperature furnace.

3. The method of producing a material powder of an oxide superconductor as defined by claim 1, wherein in the step of producing a dry powder, the solvent is removed from the solution by one method selected from the group consisting of a spray-drying method and a freeze-drying method.

4. The method of producing a material powder of an oxide superconductor as defined by claim 2, wherein in the step of producing a dry powder, the solvent is removed from the solution by one method selected from the group consisting of a spray-drying method and a freeze-drying method.
